(19) United States
(12) Patent Application Publication
(10) Pub. No.: US 2023/0155544 A1
(43) Pub. Date: May 18, 2023

(54) SYSTEM AND METHODS FOR SOLAR PANEL SHADING AND OPITMIZATION

(71) Applicant: Midas Touch Global LLC, Jericho, NY (US)

(72) Inventor: Julius Reich, Jericho, NY (US)

(73) Assignee: Midas Touch Global LLC, Jericho, NY (US)

(21) Appl. No.: 17/524,989

(22) Filed: Nov. 12, 2021

(51) Int. Cl. H02S 40/22; H02S 50/00

(52) U.S. Cl. CPC H02S 40/22; H02S 50/00

(57) ABSTRACT

A solar magnification and shading apparatus, which may include a solar panel, having a front surface; a light controlling layer, having an underside and a top side, and positioned above the front surface of the solar panel such that a total area of the underside of the light controlling layer covers at least a total area of the front surface of the solar panel; and a magnification layer, having a bottom side and positioned above the top side of the light controlling layer such that a total area of the bottom side of the magnification layer covers at least a total area of the top side of the light controlling layer.

### FIELD OF INVENTION

The present disclosure is in the field of optical devices. Specifically, optical devices used in conjunction with solar panels.

### INTRODUCTION

Use of solar panels has drastically increased over the past several years, with solar energy now accounting for a significant amount of the world’s total produced renewable energy. However, there remain many issues concerning the efficiency of solar panels. Many factors may affect the efficiency of solar panels, such as temperature, positioning, shade, or front surface soiling.

Namely, positioning of the solar panel is key to ensuring that maximum exposure time of the solar panel to a light source. Often, solar panels are static, and lose a lot of light exposure time due to the movement of the sun. Current solutions addressing this include motorizing a base of each solar panel to track the movement of the sun. However, this solution is costly and isn’t always practical depending on where the solar panel is located, such as on a residential roof, or next to an object that would prevent the solar panels movement.

Temperature is also a key factor as solar panels achieve optimal efficiency in a specific temperature window. If a solar panel gets too hot, efficiency of the solar panel begins to decrease by as much as 10-25%. Current solutions include raising the solar panel above the surface it is mounted on, or moving the inverters and combiners to a shaded area. However, these solutions do not provide for an adaptive temperature control that maintains an optimal operating temperature.

Therefore, it is desirable to have a solar panel that is able to effectively maximize light exposure and adaptively control temperature to maintain optimal output.

### SUMMARY

In an aspect of this disclosure, a solar magnification and shading apparatus may include a solar panel, have a front surface; a light controlling layer, having an underside and a top side, and positioned above the front surface of the solar panel such that a total area of the underside of the light controlling layer may cover at least a total area of the front surface of the solar panel; and a magnification layer, having a bottom side and positioned above the top side of the light controlling layer such that a total area of the bottom side of the magnification layer may cover at least a total area of the top side of the light controlling layer.

In an embodiment, the light controlling layer may be constructed from a photochromic material.

In yet another embodiment, the light controlling layer may include switchable smart glass. In such an embodiment, the solar magnification and shading apparatus may further include a power source, and a controller electrically connected to the smart glass and power source.

In another embodiment, the light controlling layer may include a plurality of light controlling layers. The first light controlling layer within the plurality of the light controlling layers may be positioned above the front surface of the solar panel such that a total area of the underside of the light controlling layer may cover at least a total area of the front surface of the solar panel. Each subsequent light controlling layer within the plurality of the light controlling panels is positioned such that the underside of the light controlling layer abuts the top side of the preceding light controlling layer.

In an embodiment, the magnification layer may include a converging lens.

In yet another embodiment, the magnification layer may include a plurality of converging lenses.

In an aspect of the disclosure, a solar magnification and shading system may include a solar panel, having a front surface; a light controlling layer, having an underside and a top side, and positioned above the front surface of the solar panel such that a total area of the underside of the light controlling layer may cover at least a total area of the front surface of the solar panel; a magnification layer, having a bottom side and positioned above the top side of the light controlling layer such that a total area of the bottom side of the magnification layer may cover at least a total area of the top side of the light controlling layer; an optical sensor; a controller; and a processor, a memory, a computer-readable storage, and instructions. The instructions, when executed by the processor may cause the system to receive, from the optical sensor, a resistance value; check the resistance value against a predetermined triggering resistance value. If the resistance value is less than the triggering resistance value, the system may activate the light controlling layer, such that it may trigger an increase in an optical opacity of the light controlling layer. If the resistance value is greater than the triggering resistance value, the system may deactivate the light controlling layer, such that the light controlling layer may be optically transparent.

In an embodiment, the optical sensor may include a photoresistor.

In yet another embodiment, the light controlling layer may include a switchable smart glass.

In another embodiment, the light controlling layer may include a plurality of light controlling layers. The first light controlling layer within the plurality of the light controlling layers may be positioned above the front surface of the solar panel such that a total area of the underside of the light controlling layer may cover at least a total area of the front surface of the solar panel. Each subsequent light controlling layer within the plurality of the light controlling panels may be positioned such that the underside of the light controlling layer abuts the top side of the preceding light controlling layer.

In an embodiment, the instructions, when executed by the processor, may cause the system to further include, if the resistance value is less than the triggering resistance value, determining a value of the difference between the resistance value and the triggering resistance value; and activating one or more additional light controlling layers based upon a magnitude of the difference.

In another embodiment, the magnification layer may be a converging lens, or a plurality of converging lenses.

In yet another embodiment, the system may further include a temperature sensor, and further instructions, when executed by the processor, may cause the system to further include, receive, from the temperature sensor, a temperature value; and check the resistance value against a predetermined threshold temperature value. If the temperature value is greater than the threshold temperature value, activating the light controlling layer, such that it may trigger an increase in an optical opacity of the light controlling layer. If the resistance value is less than the threshold temperature value, deactivating the light controlling layer, such that the light controlling layer may be optically transparent.

In an embodiment the system may further include a voltage sensor, and further instructions, when executed by the processor, may cause the system to further include, receive, from the voltage sensor, a voltage value; and check the resistance value against a predetermined threshold voltage value. If the voltage value is greater than the threshold voltage value, activating the light controlling layer, such that it may trigger an increase in an optical opacity of the light controlling layer. If the voltage value is less than the threshold voltage value, deactivating the light controlling layer, such that the light controlling layer may be optically transparent.

In an aspect of the disclosure, a computer-readable storage medium having data stored therein representing software executable by a computer, the software may have instructions to receive, from the optical sensor, a resistance value; and check the resistance value against a predetermined triggering resistance value. If the resistance value is less than the triggering resistance value, activating the light controlling layer, such that it may trigger an increase in an optical opacity of the light controlling layer. If the resistance value is greater than the triggering resistance value, deactivating the light controlling layer, such that the light controlling layer may be optically transparent

Additional aspects related to this disclosure are set forth, in part, in the description which follows, and, in part, will be obvious from the description, or may be learned by practice of this disclosure.

It is to be understood that both the forgoing and the following descriptions are exemplary and explanatory only and are not intended to limit the claimed disclosure or application thereof in any manner whatsoever.

### BRIEF DESCRIPTION OF THE DRAWINGS

The incorporated drawings, which are incorporated in and constitute a part of this specification exemplify the aspects of the present disclosure and, together with the description, explain and illustrate principles of this disclosure.

FIG. 1 is an illustrative block diagram of a system based on a computer.

FIG. 2 is an illustration of a computing machine.

FIG. 3 illustrates an exploded view of an embodiment of a solar panel module.

FIG. 4 illustrates an exploded view of an embodiment of a solar panel module.

FIG. 5 illustrates a method for detecting and optimizing output of the solar panel module.

### DETAILED DESCRIPTION

In the following detailed description, reference will be made to the accompanying drawing(s), in which identical functional elements are designated with like numerals. The aforementioned accompanying drawings show by way of illustration, and not by way of limitation, specific aspects, and implementations consistent with principles of this disclosure. These implementations are described in sufficient detail to enable those skilled in the art to practice the disclosure and it is to be understood that other implementations may be utilized and that structural changes and/or substitutions of various elements may be made without departing from the scope and spirit of this disclosure. The following detailed description is, therefore, not to be construed in a limited sense.

Those skilled in the art will realize that storage devices utilized to provide computer-readable and computer-executable instructions and data can be distributed over a network. For example, a remote computer or storage device may store computer-readable and computer-executable instructions in the form of software applications and data. A local computer may access the remote computer or storage device via the network and download part or all of a software application or data and may execute any computer-executable instructions. Alternatively, the local computer may download pieces of the software or data as needed, or process the software in a distributive manner by executing some of the instructions at the local computer and some at remote computers and/or devices.

Those skilled in the art will also realize that, by utilizing conventional techniques, all or portions of the software’s computer-executable instructions may be carried out by a dedicated electronic circuit such as a digital signal processor (“DSP”), programmable logic array (“PLA”), discrete circuits, and the like. The term “electronic apparatus” may include computing devices or consumer electronic devices comprising any software, firmware or the like, or electronic devices or circuits comprising no software, firmware or the like.

The term “firmware” as used herein typically includes and refers to executable instructions, code, data, applications, programs, program modules, or the like maintained in an electronic device such as a ROM. The term “software” as used herein typically includes and refers to computer-executable instructions, code, data, applications, programs, program modules, firmware, and the like maintained in or on any form or type of computer-readable media that is configured for storing computer-executable instructions or the like in a manner that may be accessible to a computing device.

The terms “computer-readable medium”, “computer-readable media”, and the like as used herein and in the claims are limited to referring strictly to one or more statutory apparatus, article of manufacture, or the like that is not a signal or carrier wave per se. Thus, computer-readable media, as the term is used herein, is intended to be and must be interpreted as statutory subject matter.

The term “computing device” as used herein and in the claims is limited to referring strictly to one or more statutory apparatus, article of manufacture, or the like that is not a signal or carrier wave per se, such as computing device 101 that encompasses client devices, mobile devices, wearable devices, one or more servers, network services such as an Internet services or corporate network services based on one or more computers, and the like, and/or any combination thereof. Thus, a computing device, as the term is used herein, is also intended to be and must be interpreted as statutory subject matter.

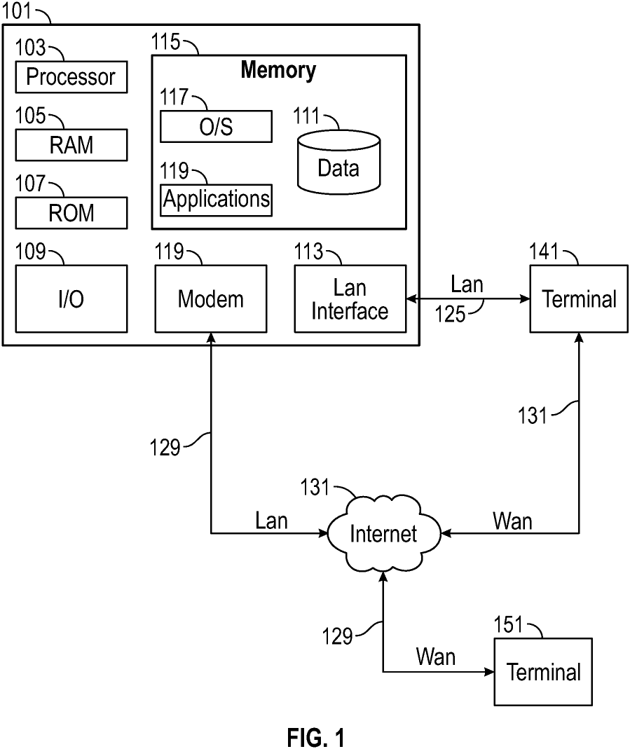

FIG. 1 is an illustrative block diagram of system 100 based on a computer 101. The computer 101 may have a processor 103 for controlling the operation of the device and its associated components, and may include RAM 105, ROM 107, input/output module 109, and a memory 115. The processor 103 will also execute all software running on the computer--e.g., the operating system. Other components commonly used for computers such as EEPROM or Flash memory or any other suitable components may also be part of the computer 101.

The memory 115 may be comprised of any suitable permanent storage technology--e.g., a hard drive. The memory 115 stores software including the operating system 117 any application(s) 119 along with any data 111 needed for the operation of the system 100. Alternatively, some or all of computer executable instructions may be embodied in hardware or firmware (not shown). The computer 101 executes the instructions embodied by the software to perform various functions.

Input/output (“I/O”) module may include connectivity to a microphone, keyboard, touch screen, and/or stylus through which a user of computer 101 may provide input, and may also include one or more speakers for providing audio output and a video display device for providing textual, audiovisual and/or graphical output.

System 100 may be connected to other systems via a LAN interface 113.

System 100 may operate in a networked environment supporting connections to one or more remote computers, such as terminals 141 and 151. Terminals 141 and 151 may be personal computers or servers that include many or all of the elements described above relative to system 100. The network connections depicted in FIG. 1 include a local area network (LAN) 125 and a wide area network (WAN) 129, but may also include other networks. When used in a LAN networking environment, computer 101 is connected to LAN 125 through a LAN interface or adapter 113. When used in a WAN networking environment, computer 101 may include a modem 127 or other means for establishing communications over WAN 129, such as Internet 131.

It will be appreciated that the network connections shown are illustrative and other means of establishing a communications link between the computers may be used. The existence of any of various well-known protocols such as TCP/IP, Ethernet, FTP, HTTP and the like is presumed, and the system can be operated in a client-server configuration to permit a user to retrieve web pages from a web-based server. Any of various conventional web browsers can be used to display and manipulate data on web pages.

Additionally, application program(s) 119, which may be used by computer 101, may include computer executable instructions for invoking user functionality related to communication, such as email, Short Message Service (SMS), and voice input and speech recognition applications.

Computer 101 and/or terminals 141 or 151 may also be devices including various other components, such as a battery, speaker, and antennas (not shown).

Terminal 151 and/or terminal 141 may be portable devices such as a laptop, cell phone, smartphone, smartwatch, or any other suitable device for storing, transmitting and/or transporting relevant information. Terminals 151 and/or terminal 141 may be other devices. These devices may be identical to system 100 or different. The differences may be related to hardware components and/or software components.

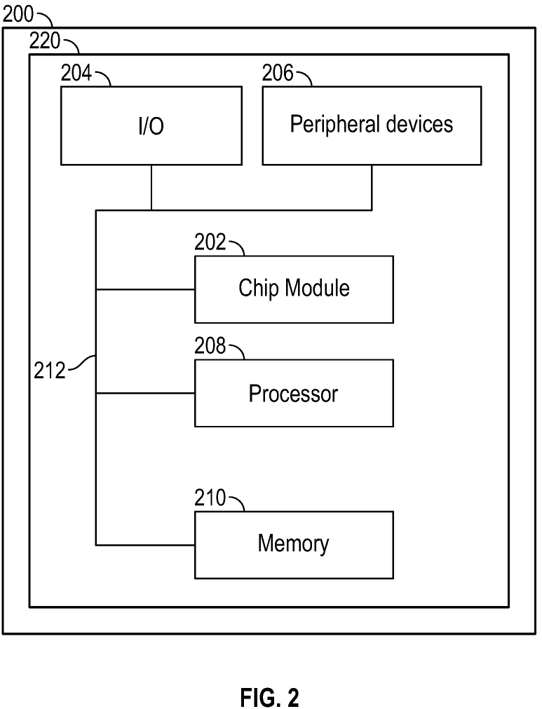

FIG. 2 shows illustrative apparatus 200. Apparatus 200 may be a computing machine. Apparatus 200 may include one or more features of the apparatus shown in FIG. 1. Apparatus 200 may include chip module 202, which may include one or more integrated circuits, and which may include logic configured to perform any other suitable logical operations.

Apparatus 200 may include one or more of the following components: I/O circuitry 204, which may include a transmitter device and a receiver device and may interface with fiber optic cable, coaxial cable, telephone lines, wireless devices, PHY layer hardware, a keypad/display control device or any other suitable encoded media or devices; peripheral devices 206, which may include counter timers, real-time timers, power-on reset generators or any other suitable peripheral devices; logical processing device 208, which may test submitted information for validity, scrape relevant information, aggregate user financial data and/or provide an auth-determination score(s) and machine-readable memory 210.

Machine-readable memory 210 may be configured to store in machine-readable data structures: information pertaining to a user, information pertaining to an account holder and the accounts which he may hold, the current time, information pertaining to historical user account activity and/or any other suitable information or data structures.

Components 202, 204, 206, 208 and 210 may be coupled together by a system bus or other interconnections 212 and may be present on one or more circuit boards such as 220. In some embodiments, the components may be integrated into a single chip. The chip may be silicon-based.

Disclosed herein are systems, apparatus and methods (“the system”) for optimizing solar panel output.

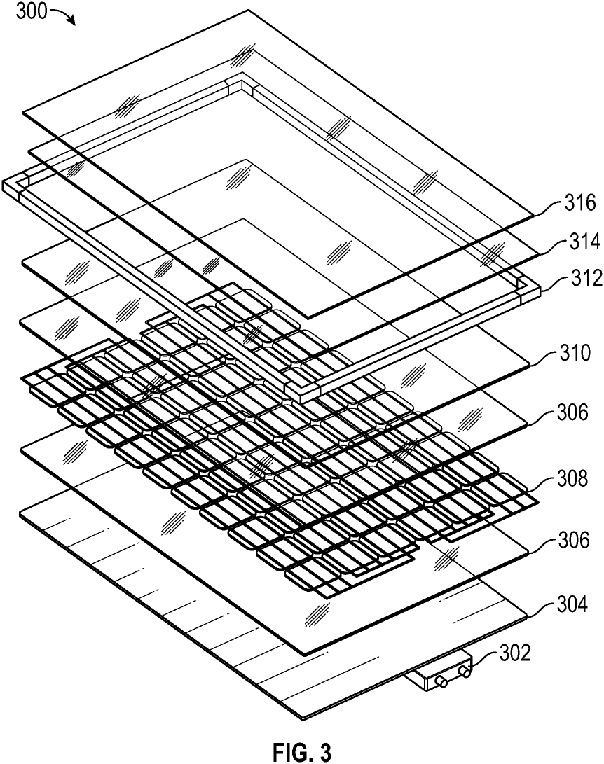

FIG. 3 shows a solar panel module 300. The solar panel module 300 may include a junction box 302. The junction box 302 may allow the solar panel module 300 to be electrically connected to a circuit. The circuit may allow the solar panel module 300 to connect to additional solar panel modules 300, or to an external battery. An external battery may be located away from the solar panel module 300. In an embodiment, the solar panel module 300 is self-contained such that it includes an internal battery and does not connect to a circuit or external battery.

The solar panel module may include a back sheet 304. The back sheet may be constructed using a polymer or combination of polymers and may be used to cover a back surface of the solar panel module 300. Such polymers may include polyethylene terephthalate, polyvinyl fluoride, polyvinylidene fluoride, or polyamide. The back sheet 304 may electrically isolate an internal circuitry of the solar panel module 300 from an external environment. The back sheet 304 may contain multiple layers, or a single layer.

In an aspect of the present disclosure, the solar panel module 300 includes an encapsulant 306. The encapsulant 306 may be used to adhere the solar cells 308 to the back sheet 304 and/or protective layer 310. In an embodiment, the encapsulant 306 is constructed from ethyl vinyl acetate. Alternatively, the encapsulant 306 may be constructed from any suitable material having low thermal resistance.

The solar panel module 300 may also include solar cells 308. Solar cells 308 may be an electrical device that converts light energy directly into electrical energy via a photovoltaic energy conversion. The solar cells 308 may include multiple cells, or just one cell. In an embodiment, the solar panel module 300 contains a plurality of electrically connected solar cells 308. The solar cells 308 may include a semiconductor material in the form of a p-n junction. Alternatively, the solar cells 308 may include any material suitable for photovoltaic energy conversion.

The solar panel module 300 may include a protective layer 310. The protective layer 310 may be optically transparent and may protect the solar cells 308 from damage. In an embodiment, the protective layer 310 may comprise tempered glass. However, any suitable material known to those skilled in the art may be used.

The solar panel module 300 may also include a frame 312, which may be used to form a structural perimeter of the back sheet 304, the encapsulant 306, the solar cells 308, and/or the protective layer 310. The frame may also form a structural perimeter of the light controlling layer(s) 314/414, or magnification layer 316. The frame may be constructed from various materials with high durability, such as steel, stainless steel, stainless steel alloys, or any other suitable material known to those skilled in the art.

In an aspect of the present disclosure, the solar panel module 300 contains a light controlling layer 314. The light controlling layer may possess an adjustable optical opacity such that it may reduce the light intensity levels upon the solar cells 308. In an embodiment, the light controlling layer 314 is a smart glass. In such an embodiment, the light controlling layer 314 may include Polymer Dispersed Liquid Crystal (“PDLC”). Alternatively, the light controlling layer 314 may include a Suspended Particle Device (“SPD”), or an Electrochromic Device (“ECD”).

The light controlling layer 314 may be electrically connected to a power source and controller, such that the optical opacity of the light controlling layer 314 may be adjusted. How the light controlling layer 314 may be electrically controlled is discussed in further detail below.

In an embodiment, the light controlling layer 314 includes a photochromic material. In such an embodiment, the light controlling layer 314 may not require a power source. The photochromic material may be configured to increase the light controlling layer’s 314 optical opacity once a threshold light intensity level has been reached.

The light controlling layer 314 may be electrically connected to a controller. In such an embodiment, the solar panel module 300 also includes an optical sensor. The optical sensor may be a photoresistor. As a non-limiting example, the controller activates the light controlling layer 314 when the optical sensor detects a light intensity level that exceeds a threshold level. The controller may activate the light controlling layer 314 based on other factors such as the temperature of the solar cells 308, or voltage level of the internal or external battery. The controller may activate the light controlling layer 314 if the temperature of the solar panels exceeds a threshold temperature. Such a threshold temperature may be a temperature above which damage may occur to the solar panels 308, such as 65° C. In another embodiment, the controller activates the light controlling layer 314 when the voltage of the internal or external battery is at a level that indicates that the battery is at full charge.

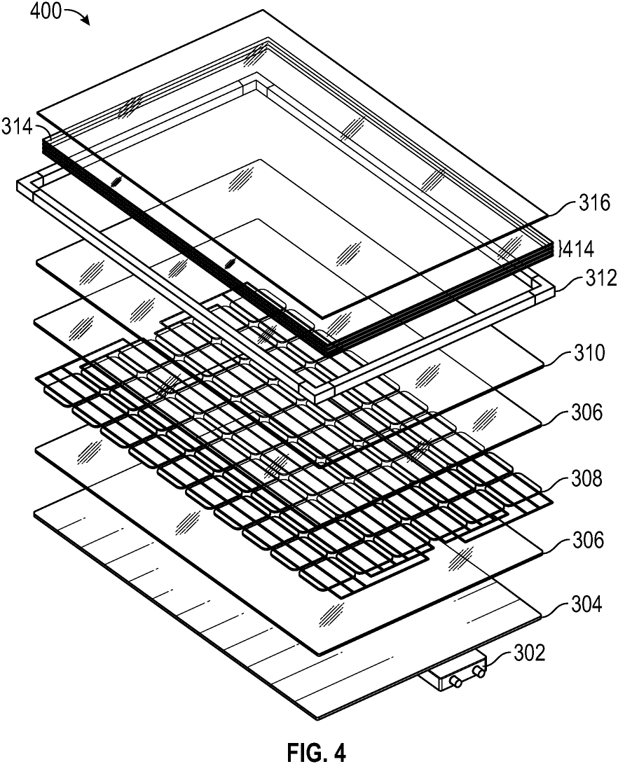

Turning to FIG. 4, an embodiment of the solar panel module 400 includes a plurality of light controlling layers 414. In such an embodiment, each light controlling layer 314 within the plurality of light controlling layers 414 is stacked on top one another to allow varying degrees of optical opacity to be achieved. As a non-limiting example, each light controlling layer 314 is individually capable of increasing the optical opacity of the layer 314 by a fixed amount. In the solar panel module 400, one or more of the light controlling layers 314 within the plurality of layers 414 may be activated to increase the total optical opacity by a desired amount. In an embodiment, there may be four layers within the plurality of layers 414. Each layer 314 may have a different thickness. In another embodiment, each light controlling layer 314 may have a light absorption of A=0.25 at 600 nm when activated, and a thickness between 0.5-3 cm. However, any suitable combination of absorption, thickness, and quantity of light controlling layers 314 may be used to achieve a desired amount of absorption or opacity when activated. The opacity of each layer 314 may be measured by the light absorbance of the material at 600 nm divided by the thickness of the material (A/mm).

In an embodiment, the plurality of light controlling layers 414 are electrically connected to a controller. In such an embodiment, the controller receives a light intensity level from the optical sensor, and depending on the detected level, activates one or more of the light controlling layers 314 within the plurality of layers 414. As a non-limiting example, the controller activates one or more light controlling layers 314 as the light intensity level increases, and deactivates one or more light controlling layers 314 as the light intensity level decreases.

The controller may activate one or more light controlling layer 314 within the plurality of light controlling layers 414 based on other factors such as the temperature of the solar cells 308, or voltage level of the internal or external battery. The controller may activate each light controlling layer 314 once the temperature of the solar panels exceeds a threshold temperature, such as 35° C. Such a threshold temperature may be a temperature above which damage may occur to the solar panels 308. In another embodiment, the controller activates each light controlling layer 314 when the voltage of the internal or external battery is at a level that indicates that the battery is at full charge. The controller may activate an increasing number of light controlling layers 314 within the plurality of layers 414 depending on the difference between the threshold value, and the detected value of any of the light intensity, temperature, or voltage.

Each light controlling layer 314 within the plurality of layers 414 may have unique properties that are different from other light controlling layers 314 within the plurality of layers 414. As a non-limiting example, each light controlling layer 314 is designed to have varying thicknesses. Each light controlling layer 314 may also be designed to filter out a specific wavelength of electromagnetic frequencies. As a non-limiting example, the plurality of light controlling layers 414 may be configured to only allow wavelengths in the range of 380-750 nm to pass through. In an embodiment, each light controlling layer may be designed to filter out certain wavelengths within the visible light spectrum. In other embodiments, each light controlling layer 314 is designed to filter different types of non-visible wavelengths. Such choice of properties of each light controlling layer may be determined by a number of factors. Such factors may include altitude of the solar panel module 400, or a location of the solar panel module 400.

The solar panel module 300 may contain a magnification layer 316. The magnification layer 316 may be located above the light controlling layer(s) 314/414. The height at which the magnification layer 316 is placed above the light controlling layer(s) 314/414 may depend on a desired focal length of the magnification layer 316.

In an embodiment, the magnification layer 316 is a convergent lens. The magnification lens may increase the light intensity level acting upon the solar cells 308 by converging an external light source onto the solar cells 308. As a non-limiting example, the magnification layer 316 magnifies light emitted by the sun. In such an example, the solar panel module 300/400 maintains an optimal output during times at which the sun is not in an optimal position (such as close to the horizon) by magnifying light entering the magnification layer 316 and redirecting the light toward the solar cells 308.

The magnification layer 316 may be made using polyethylene, glass, or any other suitable material known to those in the art. The magnification layer 316 may comprise a single lens. Alternatively, the magnification layer may comprise a plurality of smaller lenses arranged in a grid-like pattern. The magnification layer 316 may be a flat sheet. Alternatively, the magnification layer 316 may be a dome shape.

The magnification layer 316 may be configured to produce optimal light intensity levels in the worst conditions for the environment in which the solar panel module 300/400 is located. In such a configuration, one or more of the light controlling layers 314 within the plurality of layers 414 may be activated when better conditions for the environment are achieved to avoid damage to the solar cells 308.

The previously mentioned magnification layer 316, and light controlling layer(s) 314/414 may be implemented in concentrating solar-thermal power (“CSP”) technology. In such an implementation, the magnification layer 316, and light controlling layer(s) 314/414 may be configured to control the light intensity acting upon a receiver of the CSP technology.

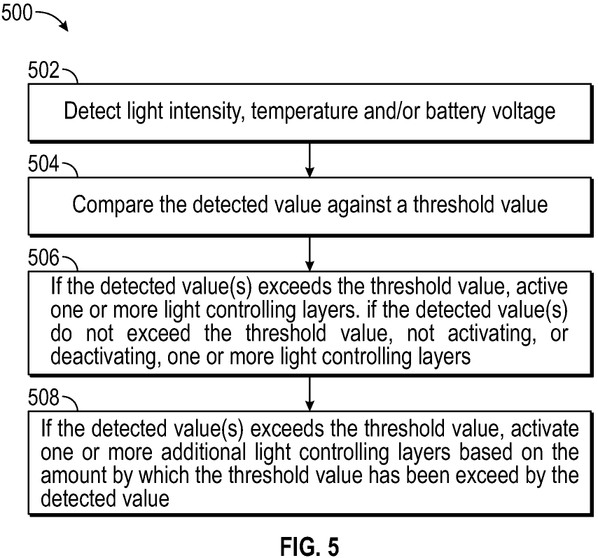

FIG. 5 illustrates a method 500 by which the system may work. Referring to step 502, the optical sensor may detect a light intensity level. In an embodiment, other sensors also provide values. In such an embodiment, the system also includes a temperature sensor, and/or a voltage sensor. There may be multiple sensors for each detected property (for example, two or more optical sensors to measure light intensity levels). The temperature sensor may be configured to detect a surface temperature of the solar cells 308. The temperature may also be configured to measure the temperature other parts of the solar panel module 300/400 that may be deemed appropriate by those skilled in the art. The voltage sensor may be configured to detect the voltage of an external battery, or an internal battery. Additional sensors may be appropriate as needed to detect other properties to which certain light intensity levels may have an adverse effect on the solar panel module 300/400.

At step 504, the detected value(s) may be received by a controller. The controller may contain a processor, a memory, a computer-readable storage, and instructions. Once the controller receives the detected value(s), the controller may compare the values against a set of defined threshold values.

Turning to step 506, if the detected value(s) exceeds the defined threshold value, the controller may activate one or more of the light controlling layers 314. If the detected value(s) does not exceed the defined threshold value, the controller does not activate, or deactivates, one or more of the light controlling layers 314. In an embodiment, activating includes increasing the optical opacity of the one or more light controlling layers 314, and deactivating includes increasing the optical opacity of the one or more light controlling layers 314.

Referring to step 508, depending on the amount the detected value(s) exceeds the threshold value, the controller may increase the number of activated light controlling panels 314. In such an embodiment, the controller’s instructions may include a maximum value at which all light controlling layers 314 within the plurality of layers 414 are to be activated. The instructions may further dictate various intervals below the maximum value at which different quantities of the light controlling layers 314 are activated. These intervals may run numerically down from the maximum number of light controlling layers 314 within the plurality of layers 414 at the maximum value, to one light controlling layer 314 within the plurality of layers 414 at the threshold value, and zero light controlling layers 314 below the threshold value.

In an embodiment, the system executes steps 502–508 at regular intervals, such that the solar panel module 300/400 maintains optimal output throughout the solar panel module’s 300/400 lifetime.

It will be apparent to those of ordinary skill in the art that methods involved in the present disclosure may be embodied in a computer program product that includes a computer usable and/or readable medium. For example, such a computer usable medium may consist of a read only memory device, such as a CD ROM disk or conventional ROM devices, or a random access memory, such as a hard drive device or a computer diskette, or flash memory device having a computer readable program code stored thereon.

Finally, other implementations of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

What is claimed is:

1. A solar magnification and shading apparatus, comprising:
a solar panel, having a front surface;
a light controlling layer, having an underside and a top side, and positioned above the front surface of the solar panel such that a total area of the underside of the light controlling layer covers at least a total area of the front surface of the solar panel; and
a magnification layer, having a bottom side and positioned above the top side of the light controlling layer such that a total area of the bottom side of the magnification layer covers at least a total area of the top side of the light controlling layer.

2. The solar magnification and shading apparatus of claim 1, wherein the light controlling layer is constructed from a photochromic material.

3. The solar magnification and shading apparatus of claim 1, wherein the light controlling layer is switchable smart glass.

4. The solar magnification and shading apparatus of claim 3, further including a power source, and a controller electrically connected to the smart glass and power source.

5. The solar magnification and shading apparatus of claim 1, wherein the light controlling layer includes a plurality of light controlling layers;
wherein the first light controlling layer within the plurality of the light controlling layers is positioned above the front surface of the solar panel such that a total area of the underside of the light controlling layer covers at least a total area of the front surface of the solar panel; and
wherein each subsequent light controlling layer within the plurality of the light controlling panels is positioned such that the underside of the light controlling layer abuts the top side of the preceding light controlling layer.

6. The solar magnification and shading apparatus of claim 1, wherein the magnification layer is a converging lens.

7. The solar magnification and shading apparatus of claim 1, wherein the magnification layer is a plurality of converging lenses.

8. A solar magnification and shading system, comprising:
a solar panel, having a front surface;
a light controlling layer, having an underside and a top side, and positioned above the front surface of the solar panel such that a total area of the underside of the light controlling layer covers at least a total area of the front surface of the solar panel;
a magnification layer, having a bottom side and positioned above the top side of the light controlling layer such that a total area of the bottom side of the magnification layer covers at least a total area of the top side of the light controlling layer;
an optical sensor;
a controller; and
a processor, a memory, a computer-readable storage, and instructions;
wherein the instructions, when executed by the processor cause the system to:
receive, from the optical sensor, a resistance value;
check the resistance value against a predetermined triggering resistance value;
if the resistance value is less than the triggering resistance value, activating the light controlling layer, such that it triggers an increase in an optical opacity of the light controlling layer;
if the resistance value is greater than the triggering resistance value, deactivating the light controlling layer, such that the light controlling layer is optically transparent.

9. The solar magnification and shading system of claim 8, wherein the optical sensor is a photoresistor.

10. The solar magnification and shading system of claim 8, wherein the light controlling layer is switchable smart glass.

11. The solar magnification and shading system of claim 8, wherein the light controlling layer includes a plurality of light controlling layers;
wherein the first light controlling layer within the plurality of the light controlling layers is positioned above the front surface of the solar panel such that a total area of the underside of the light controlling layer covers at least a total area of the front surface of the solar panel; and
wherein each subsequent light controlling layer within the plurality of the light controlling panels is positioned such that the underside of the light controlling layer abuts the top side of the preceding light controlling layer.

12. The solar magnification and shading system of claim 8, wherein the instructions, when executed by the processor, cause the system to further include:
if the resistance value is less than the triggering resistance value, determining a value of the difference between the resistance value and the triggering resistance value; and
activating one or more additional light controlling layers based upon a magnitude of the difference.

13. The solar magnification and shading system of claim 8, wherein the magnification layer is a converging lens.

14. The solar magnification and shading system of claim 8, wherein the magnification layer is a plurality of converging lenses.

15. The solar magnification and shading system of claim 8, the system further including a temperature sensor, and further instructions, when executed by the processor, cause the system to further include:
receive, from the temperature sensor, a temperature value;
check the resistance value against a predetermined threshold temperature value;
if the temperature value is greater than the threshold temperature value, activating the light controlling layer, such that it triggers an increase in an optical opacity of the light controlling layer;
if the resistance value is less than the threshold temperature value, deactivating the light controlling layer, such that the light controlling layer is optically transparent.

16. The solar magnification and shading system of claim 8, the system further including a voltage sensor, and further instructions, when executed by the processor, cause the system to further include:
receive, from the voltage sensor, a voltage value;
check the resistance value against a predetermined threshold voltage value;
if the voltage value is greater than the threshold voltage value, activating the light controlling layer, such that it triggers an increase in an optical opacity of the light controlling layer;
if the voltage value is less than the threshold voltage value, deactivating the light controlling layer, such that the light controlling layer is optically transparent.

17. A computer-readable storage medium having data stored therein representing software executable by a computer, the software having instructions to:
receive, from the optical sensor, a resistance value;
check the resistance value against a predetermined triggering resistance value;
if the resistance value is less than the triggering resistance value, activating the light controlling layer, such that it triggers an increase in an optical opacity of the light controlling layer;
if the resistance value is greater than the triggering resistance value, deactivating the light controlling layer, such that the light controlling layer is optically transparent.
